(19) United States
(12) Patent Application Publication
(10) Pub. No.: US 2026/0324432 A1
(43) Pub. Date: Oct. 15, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hao-Cheng WANG, Taichung City (TW); Hsuan-Jen WANG, Taichung City (TW); Yi-Chun LAI, Taichung City (TW); Ying-Chi CHI, Taichung City (TW)

(73) Assignee: SILICONWARE PRECISION INDUSTRIES CO., LTD., Taichung City (TW)

(21) Appl. No.: 19/331,687

(22) Filed: Sep. 17, 2025

(30) Foreign Application Priority Data
Apr. 11, 2025 (TW) 114113784

(51) Int. Cl. H01L 23/00; H01L 23/31; H01L 23/48; H01L 23/498; H01L 23/522; H01L 25/16

(52) U.S. Cl. CPC H10W 42/121; H10W 20/20; H10W 20/42; H10W 74/137; H10W 90/00; H10W 90/20; H10W 90/701; H10W 90/722; H10W 90/724

(57) ABSTRACT

An electronic package and a manufacturing method thereof are provided. A first electronic component is connected to a circuit structure. A second electronic component is stacked on the first electronic component. The second electronic component extends beyond and is cantilevered over the first electronic component. A strengthening layer is formed on the second electronic component to enhance the bending resistance.

### BACKGROUND

### 1. Technical Field

The present disclosure relates to a semiconductor packaging process, and more particularly, to an electronic package and a manufacturing method thereof.

### 2. Description of Related Art

As the electronics industry booms, electronic products are evolving toward multi-functionality and high performance. At present, the application of fifth-generation (5G) communication technology has been widely extended to fields such as the Internet of Things (IoT), Industrial Internet of Things (IIoT), cloud computing, artificial intelligence (AI), autonomous vehicles, and medical technology. With the expansion of applications, massive amounts of data are generated, requiring efficient transmission, computation, and storage. In particular, the surge in data transmission demand has prompted the industry to replace “electricity” with “light” as the carrier of data transmission, enhancing transmission capacity, efficiency, and distance while reducing energy consumption during data transmission. Against this backdrop, co-packaged optical components (Co-Packaged Optics) have become a development trend in semiconductor and packaging technology.

Please refer to FIG. 1, where a conventional semiconductor package 1 utilizing silicon photonics technology includes: a first circuit structure 10, an electronic integrated circuit component 11 and a plurality of conductive pillars 12 bonded to the first circuit structure 10, an encapsulation layer 13 encapsulating the electronic integrated circuit component 11 and the plurality of conductive pillars 12, a second circuit structure 14 formed on the encapsulation layer 13, and a photonic integrated circuit component 15 disposed on the second circuit structure 14. One end of the photonic integrated circuit component 15 is connected to an optical fiber (now shown), and a bracket is disposed below the connection point of the photonic integrated circuit component 15 and the optical fiber.

However, in the aforementioned semiconductor package, the photonic integrated circuit component extends beyond the second circuit structure in a cantilever design, making it susceptible to bending and breakage during optical fiber insertion and removal. Additionally, when processing signals between the photonic integrated circuit component and the electronic integrated circuit component, transmission must occur through the metal traces of the second circuit structure. This results in an excessively large and thick device, which is unfavorable for miniaturization of electronic products. Furthermore, the extended signal transmission path leads to signal loss, causing problems in the application of end products.

Therefore, how to overcome the above-mentioned problems of the prior art has become an urgent issue to be solved.

### SUMMARY

In view of the various deficiencies of the prior art, the present disclosure provides an electronic package, which comprises: a circuit structure; a first electronic component disposed on the circuit structure; a second electronic component disposed on the first electronic component, the second electronic component extending beyond and being cantilevered over the first electronic component; and a strengthening layer formed on the second electronic component.

The present disclosure also provides a method of manufacturing an electronic package, and the method comprises: providing a circuit structure; disposing a first electronic component on the circuit structure; disposing a second electronic component on the first electronic component, the second electronic component extending beyond and being cantilevered over the first electronic component; and forming a strengthening layer on the second electronic component.

In the aforementioned electronic package and method, the first electronic component is an electronic integrated circuit component.

In the aforementioned electronic package and method, the first electronic component is formed with a plurality of conductive vias electrically connected to the circuit structure.

In the aforementioned electronic package and method, the second electronic component is a photonic integrated circuit component.

In the aforementioned electronic package and method, a length by which the second electronic component extends beyond the first electronic component is at least 30% of a length of the second electronic component.

In the aforementioned electronic package and method, the second electronic component is connected to the first electronic component via a plurality of conductive bumps and is electrically connected to the first electronic component.

In the aforementioned electronic package and method, a thickness of the strengthening layer is at least 1 millimeter.

In the aforementioned electronic package and method, a thickness of the strengthening layer is proportional to a length by which the second electronic component extends beyond the first electronic component.

In the aforementioned electronic package and method, the strengthening layer is a dielectric layer or a metal layer.

In the aforementioned electronic package and method, the circuit structure includes an insulation layer and a circuit layer bonded to the insulation layer, and wherein a surface of the circuit structure is formed with a plurality of conductive contacts, and another surface of the circuit structure is disposed with a plurality of conductive components.

As can be seen from the above, the electronic package and the manufacturing method thereof according to the present disclosure mainly involves connecting the first electronic component to the circuit structure and stacking the second electronic component on the first electronic component. The first electronic component is an electronic integrated circuit component, and the second electronic component is a photonic integrated circuit component, forming a three-layer, vertically stacked optical engine. At the same time, by forming the plurality of conductive vias in the photonic integrated circuit component, the photonic integrated circuit component, the electronic integrated circuit component, and the circuit structure may be directly electrically connected to each other through the plurality of conductive vias, thereby shortening the signal transmission path and improving the transmission rate. Additionally, the strengthening layer may be formed on the photonic integrated circuit component, enhancing its bending resistance and avoiding cracking during optical fiber insertion and removal, which may occur due to the extending of the photonic integrated circuit component.

### BRIEF DESCRIPTION OF THE DRAWINGS

FIG. 1 is a schematic cross-sectional view of a conventional semiconductor package utilizing silicon photonics technology.

FIG. 2A to FIG. 2C are schematic cross-sectional views illustrating a method for manufacturing an electronic package according to the present disclosure.

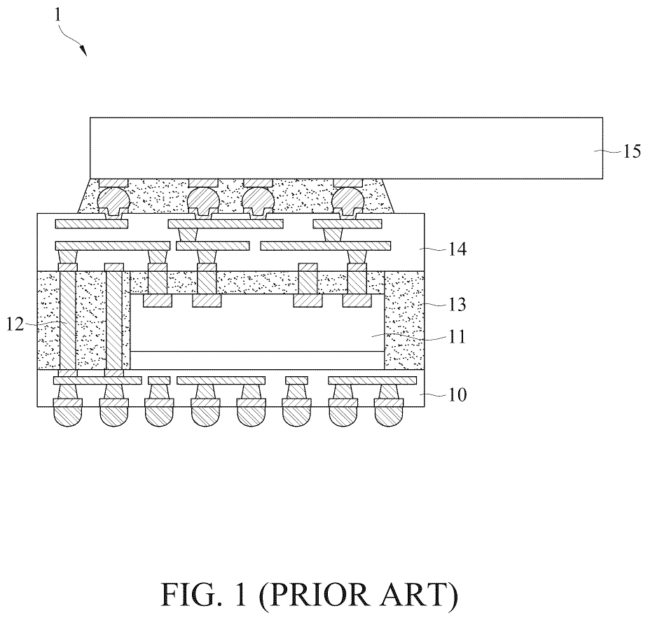

### DETAILED DESCRIPTION

The following describes the embodiments of the present disclosure with examples. Those skilled in the art can readily understand additional advantages and effects of the present disclosure from the contents disclosed in this specification.

It should be understood that the structures, proportions, dimensions, and the like in the accompanying figures are used for illustrative purposes to facilitate the perusal and comprehension of the contents disclosed in the present specification by one skilled in the art, rather than to limit the practical applications of the present disclosure. Any modification of the structures, alteration in proportional relationships, or adjustment to dimensions without affecting the intended effects and achievable proposes should still be considered within the scope defined by the technical contents disclosed in the present specification. Additionally, terms such as “upper,” “lower,” “on,” “below,” “first,” “second,” “a,” “one,” and similar descriptors are solely for clarity and explanation, rather than to restrict the practicable scope of the present disclosure. Therefore, alterations or adjustments to their relative relationships without essentially altering the technical contents should still be regarded as within the practicable scope of the present disclosure.

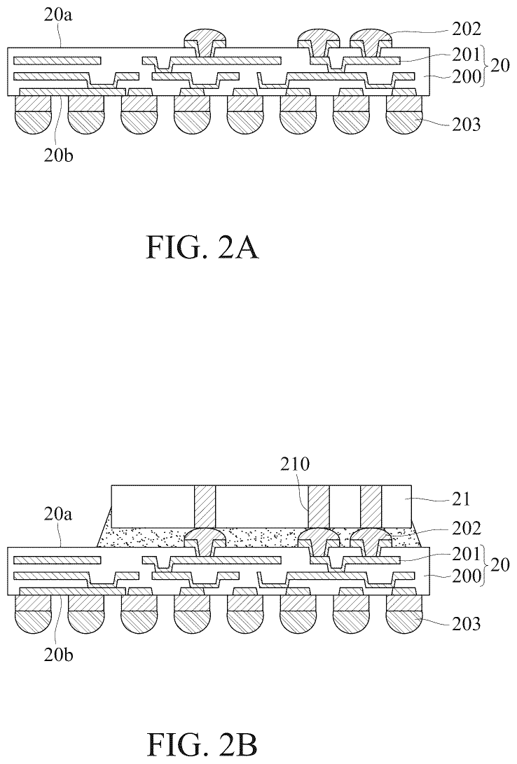

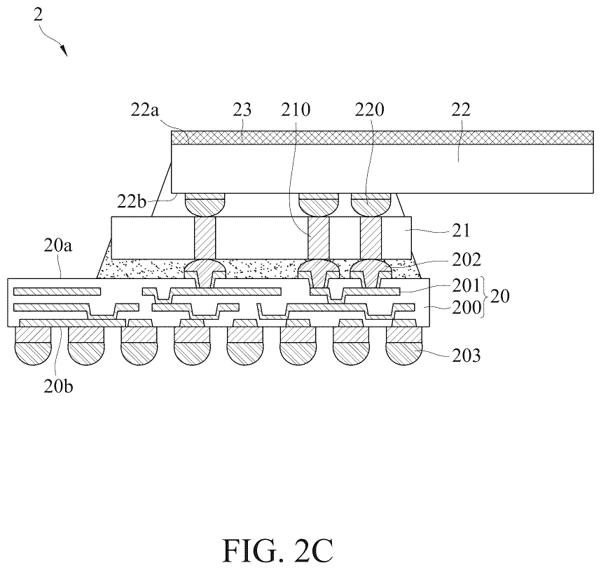

FIG. 2A to FIG. 2C are schematic cross-sectional views illustrating a method for manufacturing an electronic package 2 according to the present disclosure.

As shown in FIG. 2A, a circuit structure 20 is provided and has a first surface 20a and a second surface 20b opposite to the first surface 20a. The circuit structure 20 includes at least one insulation layer 200 and at least one circuit layer 201 bonded to the insulation layer 200. The circuit layer 201 may be made of copper or other conductive materials. The insulation layer 200 may be made of a dielectric material such as polybenzoxazole (PBO), polyimide (PI), prepreg (PP), or the like.

The first surface 20a of the circuit structure 20 is formed with a plurality of conductive contacts 202, such as bonding pads or conductive bumps. The second surface 20b is disposed with a plurality of conductive components 203, such as solder balls.

As shown in FIG. 2B, a first electronic component 21 is attached to the first surface 20a of the circuit structure 20 and is electrically connected to the circuit structure 20.

The first electronic component 21 is, for example, an electronic integrated circuit (EIC) component. The first electronic component 21 is formed with a plurality of conductive vias 210, such as through-silicon vias (TSVs). The plurality of conductive vias 210 are electrically connected to the conductive contacts 202 of the circuit structure 20.

In one embodiment, an underfill may be formed between the first electronic component 21 and the circuit structure 20.

As shown in FIG. 2C, a second electronic component 22 is attached to the first electronic component 21 and is electrically connected to the first electronic component 21. The second electronic component 22 extends beyond the first electronic component 21 and is cantilevered over a side of the first electronic component 21.

The second electronic component 22 is, for example, a photonic integrated circuit (PIC) component. The length by which the second electronic component 22 extends beyond the first electronic component 21 is at least 30% of a length of the second electronic component 22.

The second electronic component 22 has a first side 22a and a second side 22b opposite to the first side 22a. The second electronic component 22 is connected to the first electronic component 21 via the second side 22b through a plurality of conductive bumps 220 (such as solder bumps or copper bumps) and is electrically connected to the plurality of conductive vias 210. Additionally, an underfill may be formed between the first electronic component 21 and the second electronic component 22.

In the present disclosure, the plurality of conductive vias 210 are formed in the first electronic component 21 (i.e., EIC) to allow the second electronic component 22 (i.e., PIC) and the circuit structure 20 to be directly stacked and electrically connected. This forms a three-dimensional stacked structure that shortens the interconnection distances among the first electronic component 21, the second electronic component 22, and the circuit structure 20, thereby improving the signal transmission efficiency.

Additionally, a strengthening layer 23 is formed on the first side 22a of the second electronic component 22, thereby finalizing the electronic package 2 of the present disclosure.

The strengthening layer 23 is, for example, a dielectric layer (made of such as polypropylene [PP] or polyethylene terephthalate [PET or PETP]) or a metal layer (made of such as copper). The thickness of the strengthening layer 23 is at least 1 millimeter (mm), enhancing the bending resistance. In one embodiment, the thickness of the strengthening layer 23 is proportional to the length by which the second electronic component 22 extends beyond the first electronic component 21.

The strengthening layer 23 may be formed on the second electronic component 22 after the second electronic component 22 is connected to the first electronic component 21. Alternatively, the strengthening layer 23 may be formed on the second electronic component 22, and then the second electronic component 22 is connected to the first electronic component 21.

According to the aforementioned manufacturing method, an electronic package 2 is provided. The electronic package 2 comprises: a circuit structure 20; a first electronic component 21 disposed on the circuit structure 20; a second electronic component 22 disposed on the first electronic component 21; and a strengthening layer 23 formed on the second electronic component 22.

The first electronic component 21 is an electronic integrated circuit component and is formed with a plurality of conductive vias 210 electrically connected to the circuit structure 20.

The second electronic component 22 is a photonic integrated circuit component, and extends beyond and is cantilevered over a side of the first electronic component 21. The second electronic component 22 is electrically connected to the plurality of conductive vias 210 of the first electronic component 21 through a plurality of conductive bumps 220.

The strengthening layer 23 is a dielectric layer or a metal layer, and enhances overall bending resistance.

To sum up, the electronic package and the manufacturing method thereof according to the present disclosure mainly involves connecting the first electronic component to the circuit structure and stacking the second electronic component on the first electronic component. The first electronic component is an electronic integrated circuit component, and the second electronic component is a photonic integrated circuit component, forming a three-layer, vertically stacked optical engine. At the same time, by forming the plurality of conductive vias in the photonic integrated circuit component, the photonic integrated circuit component, the electronic integrated circuit component, and the circuit structure may be directly electrically connected to each other through the plurality of conductive vias, thereby shortening the signal transmission path and improving the transmission rate. Additionally, the strengthening layer may be formed on the photonic integrated circuit component, enhancing its bending resistance and avoiding cracking during optical fiber insertion and removal, which may occur due to the extending of the photonic integrated circuit component.

The foregoing embodiments are provided to illustrate the principles and effects of the present disclosure rather than to limit the scope of the present disclosure. Those skilled in the art may modify and alter the above embodiments without departing from the spirit and scope of the present disclosure. Therefore, the scope of protection regarding the present disclosure should be as defined in the accompanying claims listed below.

What is claimed is:

1. An electronic package, comprising:
a circuit structure;
a first electronic component disposed on the circuit structure;
a second electronic component disposed on the first electronic component, the second electronic component extending beyond and being cantilevered over the first electronic component; and
a strengthening layer formed on the second electronic component.

2. The electronic package of claim 1, wherein the first electronic component is an electronic integrated circuit component.

3. The electronic package of claim 1, wherein the first electronic component is formed with a plurality of conductive vias electrically connected to the circuit structure.

4. The electronic package of claim 1, wherein the second electronic component is a photonic integrated circuit component.

5. The electronic package of claim 1, wherein a length by which the second electronic component extends beyond the first electronic component is at least 30% of a length of the second electronic component.

6. The electronic package of claim 1, wherein the second electronic component is connected to the first electronic component via a plurality of conductive bumps and is electrically connected to the first electronic component.

7. The electronic package of claim 1, wherein a thickness of the strengthening layer is at least 1 millimeter.

8. The electronic package of claim 1, wherein a thickness of the strengthening layer is proportional to a length by which the second electronic component extends beyond the first electronic component.

9. The electronic package of claim 1, wherein the strengthening layer is a dielectric layer or a metal layer.

10. The electronic package of claim 1, wherein the circuit structure includes an insulation layer and a circuit layer bonded to the insulation layer, and wherein a surface of the circuit structure is formed with a plurality of conductive contacts, and another surface of the circuit structure is disposed with a plurality of conductive components.

11. A method of manufacturing an electronic package, comprising:
providing a circuit structure;
disposing a first electronic component on the circuit structure;
disposing a second electronic component on the first electronic component, the second electronic component extending beyond and being cantilevered over the first electronic component; and
forming a strengthening layer on the second electronic component.

12. The method of claim 11, wherein the first electronic component is an electronic integrated circuit component.

13. The method of claim 11, wherein the first electronic component is formed with a plurality of conductive vias electrically connected to the circuit structure.

14. The method of claim 11, wherein the second electronic component is a photonic integrated circuit component.

15. The method of claim 11, wherein a length by which the second electronic component extends beyond the first electronic component is at least 30% of a length of the second electronic component.

16. The method of claim 11, wherein the second electronic component is connected to the first electronic component via a plurality of conductive bumps and is electrically connected to the first electronic component.

17. The method of claim 11, wherein a thickness of the strengthening layer is at least 1 millimeter.

18. The method of claim 11, wherein a thickness of the strengthening layer is proportional to a length by which the second electronic component extends beyond the first electronic component.

19. The method of claim 11, wherein the strengthening layer is a dielectric layer or a metal layer.

20. The method of claim 11, wherein the circuit structure includes an insulation layer and a circuit layer bonded to the insulation layer, and wherein a surface of the circuit structure is formed with a plurality of conductive contacts, and another surface of the circuit structure is disposed with a plurality of conductive components.
